(19) United States
(12) Patent Application Publication
(10) Pub. No.: US 2009/0320894 A1
(43) Pub. Date: Dec. 31, 2009

(54) METHOD FOR PREPARING NANOCRYSTALLINE TRANSPARENT FILMS OF TUNGSTEN OXIDE

(76) Inventors: Fabio Angiuli, Ferrara (IT); Roberto Argazzi, Portomaggiore (IT); Stefano Caramori, Viconovo (IT); Carlo Alberto Bignozzi, Ferrara (IT)

Correspondence Address: DICKSTEIN SHAPIRO LLP, 1825 EYE STREET NW, Washington, DC, 20006-5403, US

(21) Appl. No.: 12/279,690

(22) PCT Filed: Feb. 17, 2006
(86) PCT No.: PCT/IT06/00084

§ 371 Date: Feb. 6, 2009

(51) Int. Cl. H01L 31/042; B05D 5/06; C09D 1/00; G02F 1/15

(52) U.S. Cl. 136/244; 427/126.2; 106/286.1; 359/265

(57) ABSTRACT

The object of the present invention is the preparation, through a sol-gel method, of a tungsten oxide (WO₃)-based colloidal paste that allows providing transparent films on conductive glasses in an easy and cost-effective manner. Particularly, the present invention relates to a method for preparing a substrate coated with at least one thick layer of tungsten oxide, comprising at least one step of coating said substrate with a colloidal solution of tungsten oxide obtained with the sol-gel method, said colloidal solution being additioned with a thickener and a surfactant.

The object of the present invention is the preparation, through a sol-gel method, of a tungsten oxide (WO₃)-based colloidal paste that allows providing transparent films on conductive glasses in an easy and cost-effective manner. The conductive glasses, thus modified by the WO₃ film can be used to make electrochromic devices for building glass walls, photoelectrocatalytic devices for the oxidation of organic contaminants and the parallel reduction of water to hydrogen, and for the production of transparent photoanodes that can be tandem-coupled with traditional photovoltaic or photoelectrochemical solar cells, known as Dye Sensitized Solar Cells (DSSCs), in order to obtain the reduction of water to hydrogen by means of solar energy.

Methods for WO₃ deposition by means of vacuum sputtering are known and widely used in the industrial field. These methods use expensive equipment, particularly when the surfaces to be processed are large sized and require long deposition times to obtain thickness values in the range of microns.

As an alternative to the sputtering deposition method, chemical methods can be used for preparing WO₃ colloidal suspensions. These methods have attracted attention because the method for the preparation and deposition of the WO₃ semiconductor layer, which in principle may be carried out by means of screen printing or doctor blading, is cost-effective. The procedures known in the literature do not mention, however, examples of simple preparations of thick films. With “thick films” is meant 2˜3 micron thick films, which are required by the electrochromic devices in order to obtain a good colour contrast and by the photoelectrochemical devices to generate high photocurrents.

Augustynski's group reports in the literature the preparation of tungstic acid colloidal suspensions in water by means of sol-gel method, with procedures involving the transformation of sodium tungstate, Na₂WO₃, to tungstic acid, H₂WO₃, by using ion exchange resins. This method requires a long time, and obtaining the WO₃ film from the tungstic acid colloid requires the deposition and subsequent heating of at least 6 different layers to obtain a 2 micron-thick film.

The present invention relates to a method for directly preparing colloidal WO₃ suspensions which allow providing 2-3 micron thick films by depositing one or at most two layers of colloidal suspension on a conductive glass.

It has been seen that the object described above can be achieved by increasing the density while decreasing the surface tension of the WO₃ colloidal suspension.

### BRIEF DESCRIPTION OF THE DRAWINGS

FIG. 1 shows two electronic microscope images of the WO₃ coating as obtained with the inventive method;

FIG. 2 shows the electronic absorption spectra in the ultraviolet and visible regions of two films obtained through an individual (lower curve) and a double (upper curve) deposition.

FIG. 3 shows the variations in the absorption spectrum of the WO₃ film corresponding to the colour variations;

FIG. 4 shows the photoaction spectrum of a WO₃ film deposited on a conductive glass (based on Fluorine-doped SnO₂, 10 ohm/square surface resistance);

FIG. 5 illustrates a device where a WO₃ photoanode is serially connected to a sensitized titanium dioxide solar cell, DSSC.

The sol-gel technique is used for forming the WO₃ suspension.

This technique provides the formation of a clear and transparent WO₃ colloidal solution. This colloidal solution is formed by treating a tungstate salt, preferably a tungstate of an alkali metal such as sodium tungstate (Na₂WO₃), in acidic medium to give a WO₃ gel. This reaction is carried out in a protic solvent, preferably water. The acidizer is preferably a strong mineral acid, such as hydrochloric acid.

To obtain the colloidal solution from the WO₃ gel, thus prepared, the gel is added portionwise to an acidic solution, preferably in the same solvent as used in the first step of the method, which is hold at a temperature preferably ranging between 50° C. and 100° C., more preferably between 65° C. and 75° C. In this case, the acidizer is preferably a carboxylic or polycarboxylic acid such as oxalic, malonic, succinic, glutaric acid.

A transparent and colourless WO₃ colloidal solution is thus obtained.

The preparation being the object of the present invention is thus characterized by adding a thickener and a surfactant to the WO₃ colloidal solution prepared above. The thickener is preferably a polyethylene glycol-based additive. The surfactant is preferably a non-ionic surfactant. These additives have the function of increasing the density and decreasing the surface tension of the WO₃ aqueous colloidal solution. This allows providing a colloidal paste that can be quickly coated on a solid surface by means of screen printing or doctor blading. The thick films obtained with this method have a considerable smoothness and have optimum electrochromic, photoelectrocatalytic and photoelectrochemical characteristics.

The thickener is preferably polyethylene glycol reacted with bisphenol A diglycidyl ether, also known as Carbowax 20000. Alternatively, Mannitol, Glycerol, Ethylenglycol and 200 to about 1000 (average) MW poly PEG can be used.

The surfactant, preferably a non-ionic surfactant, in a particularly preferred embodiment of the invention, is a polyethylene glycol-based surfactant, more preferably selected from polyethylene glycol or a polyethylene glycol-ether or a polyethylene glycol-hexadecyl-ether, or a polyethylene glycol-octadecyl-ether or a polyethylene glycol-dodecyl-ether or a polyoxyethylene-stearyl-ether. In particular, the surfactant can be selected from a group of non-ionic surfactants comprising: Triton X-45, Triton X-100, Triton X-114 Triton X-165, Triton X-305, Triton X-405, Triton X 705-70 Triton CF10, Brij 30, Brij 35 P, Brij 52, Brij 56, Brij 58 P, Brij 72, Brij 76, Brij 78 P, Brij 92V, Brij 96 V.

The thickener is added in an amount ranging between 15% and 25% w/w, preferably between 18% and 23% w/w.

The surfactant is added in an amount ranging between 0.5% and 4% by weight, preferably between 1% and 3% by weight of colloidal paste.

The thickener and the surfactant allow obtaining a WO₃ colloidal paste having optimum surface density and tension to obtain a thick and homogeneous film.

The deposition of the WO₃ colloidal solution thus obtained on the substrate to be coated, particularly a glass plate, is preferably carried out by the “doctor blading” method (also known as “tape casting”). This method provides that the plate is coated with the colloidal solution of the invention and levelled to the desired thickness by passing a suitable blade (“doctor blade”) thereon.

The substrate thus coated is then subjected to a sintering step, normally at temperatures ranging between 500° C. and 600° C. A WO₃ film is obtained, which is perfectly transparent and 2-3 micron thick. The deposition and subsequent heating of the paste can be repeated once again without the characteristics of adhesion, transparency and stability of the film being altered.

The method described in the present invention is simple, cost-effective, reproducible and can be extended to industrial outputs. The preparation of the WO₃-based colloidal paste is now described by way of example.

### EXAMPLE 1

### Preparation of a WO₃-Based Colloidal Paste

2.5 g Na₂WO₃ is dissolved in 50 ml H₂O mQ. 20 ml of conc. HCl is added dropwise to the solution. (about 1 drop/second). A light yellow colloidal precipitate of a gelatinous consistency is formed, which is then washed three times with H₂O mQ at pH 2 to remove the NaCl resulting from the precipitation reaction and the unreacted Na₂WO₃, if present. The separation of the wash water from the colloid is carried out by means of 4000 rpm centrifugation for 3 minutes.

The WO₃ colloidal precipitate is added to a solution consisting of 3-5 g oxalic acid in 10 ml H₂O mQ that is maintained at a temperature of 90° C. Additions are carried out portionwise such that they can be completely dissolved.

After the colloid has been completely dissolved, the perfectly transparent solution is cooled at room temperature for about 10 minutes under stirring. A precipitate is formed which results from the crystallization of the excess oxalic acid that is subsequently vacuum filtered with a sintered glass filter, porosity #4. To the filtered solution is added 20% w/w Carbowax 20000, as the thickener, and about 0.015-0.030 g Triton X-100, preferably 0.0020 g, per gram of colloidal paste, as the surfactant, such as to provide the same with optimum density and surface tension for an even distribution on glass surfaces and preparation of transparent films. The films obtained by means of the doctor blading technique are finally sintered at a temperature of 550° C. for 15 minutes.

Characterization of the WO₃-Based Films

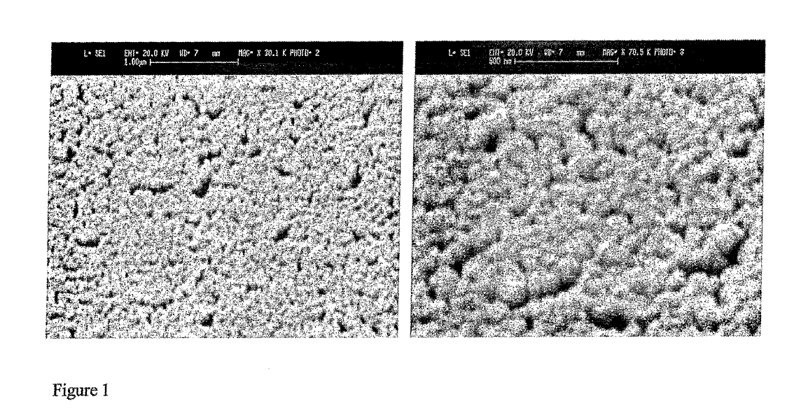

FIG. 1 shows the images of an exemplary WO₃ transparent film obtained with a scanning electron microscope.

From the images in FIG. 1, it can be seen that the colloidal particles have an average diameter of about 50-100 nm and intimate contact each other, thereby ensuring good electron interaction.

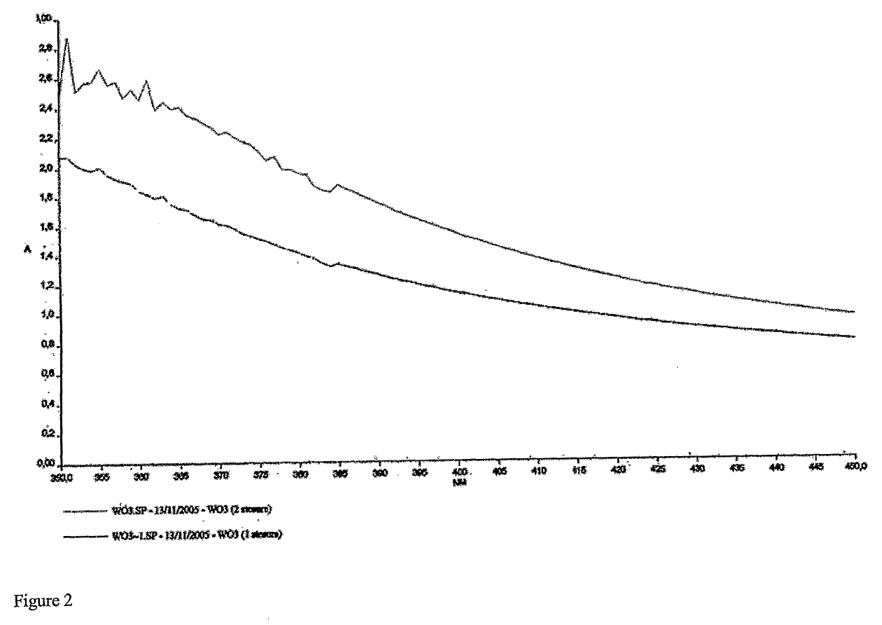

FIG. 2 shows the electronic absorption spectra in the ultraviolet and visible regions of two films obtained through an individual (lower curve) and a double (upper curve) deposition.

FIG. 2 shows that optical density values proximate to 2 at 350 nm (99% incident photons are absorbed) and optical density values equal to 1 in the 400-450 nm wavelength range (90% incident photons are absorbed) can be obtained by an individual deposition of WO₃ film. The deposition of a subsequent layer, after heating and cooling the first one, allows enhancing the absorption in the UV-visible spectrum regions.

### APPLICATIVE EXAMPLES

### a) Electrochromic Devices

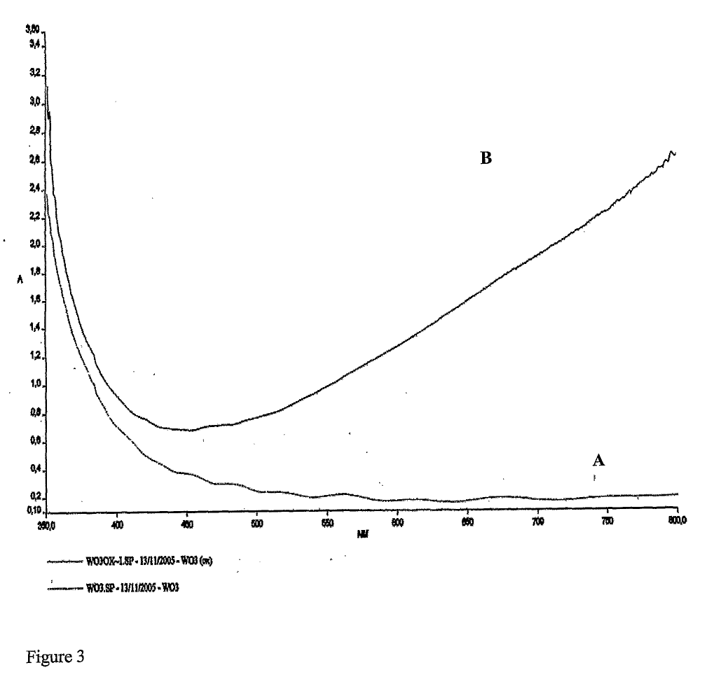

The electrochromic characteristics of a WO₃ film (1.2 micron thick) that is obtained by depositing an individual layer of colloidal paste and deposited on conductive glass are illustrated in FIG. 3.

Measurements have been carried out in the presence of a lithium perchlorate (LiClO₄) solution 0.1M in methoxypropionitrile, acetonitrile or other organic solvent that is not oxidized at potentials of about +1V, and in a cell consisting of the WO₃ electrode, as the working electrode, a platinum counter-electrode and a silver electrode, as the reference electrode.

−1V polarization of the WO₃ electrode is shown by the appearance of a blue colour. This phenomenon is due to the injection of electrons in the WO₃ conduction band. The excess electron charge is stabilized by the presence of lithium ions (Li⁺) capable of percolating through the WO₃ nanoparticles. The blue colour disappears when WO₃ is +1V polarized.

The colour process variation from transparent to blue is reversible and no alteration is seen on the film when potential differences are applied in repeated cycles between −1V and +1V.

FIG. 3 shows the variations in the absorption spectrum of the WO₃ film corresponding to the colour variations. In normal conditions, the transparent WO₃ film has a small absorption in the spectral region from 380 to 450 nm. After it is reduced (−1v), an optical density increase is observed (curve B) in the visible spectral region from 400 to 800 nm.

Since the absorption spectrum of the reduced WO₃ film extends to the near-infrared region, by applying these films deposited on conducting glasses building glass walls can be obtained, which in addition to changing colours, can filter the heat from solar radiation.

### b) Photoelectrocatalytic Devices for the Oxidation of Organic Species in Aqueous Solution and Hydrogen Production

By irradiating WO₃ film with solar light, electrons can be promoted from the valence band to the conduction band of the semiconductor. The absorption spectrum of the semiconductor, in fact, has an absorption band from 450 nm that extends to the ultraviolet region. Under UV-visible irradiation conditions, when 0.7-1 V potential difference is applied between a WO₃ film on conductive glass and a platinum electrode, electrons can be promoted to the platinum electrode by maintaining a defect of electron charge, or well, on the WO₃ electrode. The oxidizing power of the photogenerated wells is high, amounting to about 2.5 eV, and this allows oxidizing the water or organic species present in aqueous solution and simultaneously reducing the water at the platinum electrode with production of hydrogen.

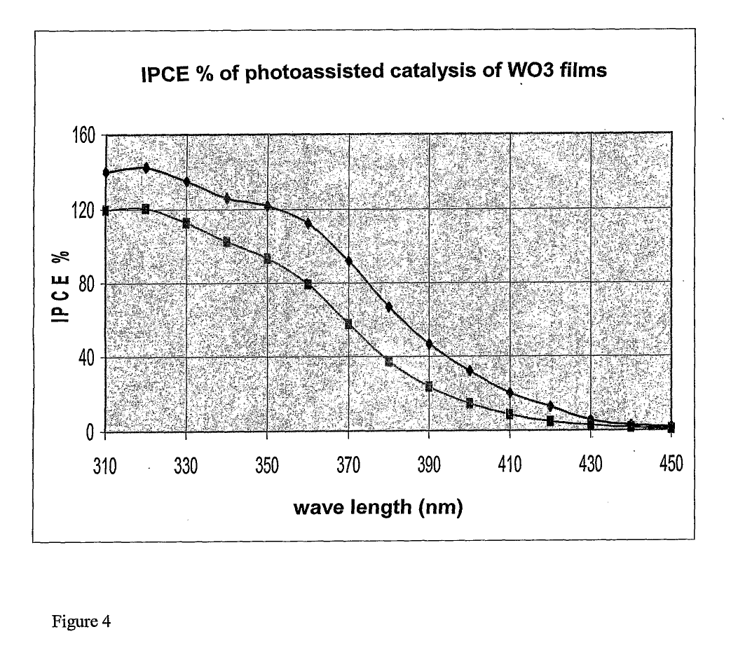

FIG. 4 shows the photoaction spectrum of a WO₃ film deposited on a conductive glass (based on Fluorine-doped SnO₂, 10 ohm/square surface resistance); The spectrum has been obtained by irradiating with monochromatic light the WO₃ photoanode coupled with a platinum counter-electrode and a saturated calomel electrode, dipped in an aqueous solution containing HClO₄ 1 M and 10% v/v methyl alcohol.

FIG. 4 illustrates that the system can generate photocurrents also in the visible spectrum, from 450 nm. The photocurrent values (IPCE %) exceed 100% for the oxidation of methyl alcohol to formaldehyde such as Augustinski's group had previously observed.

To the luminous excitation of the semiconductor with light having wavelength less than 450 nm, there corresponds in fact the promotion of an electron to the conduction band e⁻ (CB) and the formation of a well in the valence band h⁺ (VB), equation 1,

hv . . . WO₃→e⁻(CB)+h⁺(VB) (1)

The well, due to its oxidizing power, is capable of oxidizing the methyl alcohol, in contact with the WO₃ film, according to the equation 2,

h⁺(VB)+CH₃OH→.CH₂OH+H⁺ (2)

with formation of the hydroxymethyl radical, .CH₂OH and a proton, H⁺. The following oxidation of the hydroxymethyl radical to formaldehyde allows injecting a second electron in the conduction band of the semiconductor, equation 3

.CH₂OH→HCHO+H⁺+e⁻(CB) (3)

The fact that the value of the photocurrent measured in monochromatic light (IPCE) exceeds 100% testifies the system efficacy in oxidizing the methyl alcohol present in the aqueous solution. Finally, it should be noted that the oxidation of the methyl alcohol, as with other organic species, can be mediated and promoted by the formation of .OH radicals deriving from the oxidation of a water molecule on the WO₃ electrode, eq 4.

H₂O+h⁺(VB)→.OH+H⁺ (4)

In addition, FIG. 4 indicates that the subsequent deposition of two layers of the WO₃ colloidal paste being the object of the present invention allows increasing the value of the photocurrents generated by the system.

### b) Photo Electrochemical Devices (Tandem Cells) for the Oxidation of Organic Species in Aqueous Solution and Hydrogen Production

The characteristics of transparency of the WO₃ film being the object of the present invention, together with their oxidizing capacity, allow obtaining photoelectrochemical devices for the reduction of water to hydrogen and the simultaneous oxidation of water to oxygen or the oxidation of organic species present in aqueous solution, by means of the solar energy.

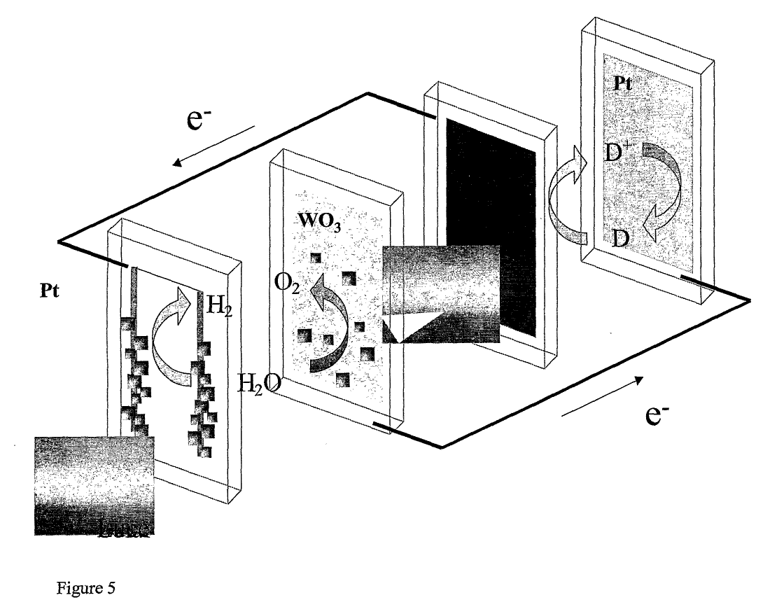

FIG. 5 illustrates a device where a WO₃ photoanode is serially connected to a sensitized titanium dioxide solar cell, DSSC. A similar connection can be provided with a traditional photovoltaic solar cell, thus generating the same effect: the incident light on the WO₃ film produces a charge separation with transfer of the generated electrons to the photoelectrochemical (or photovoltaic) device, whereas the wells can oxidize the water or organic species being in the solution.

That part of light which is not absorbed by the WO₃ film is transmitted to the photoelectrochemical (or photovoltaic) device, which when excited produces electrons that can be transferred through an external circuit to a platinum electrode. The reduction of water to hydrogen finally takes place on this electrode.

The efficacy of these devices, which are known as the tandem cells, mainly depends on the transparency characteristics and the thickness of the WO₃ film.

In the present invention, there has been developed the preparation of colloidal WO₃ suspensions, which allow providing thick films through the deposition of one or at most two layers of colloidal paste by means of screen printing or doctor blading. The preparation is reproducible, easy to apply and is characterized by the use of a thickener and surfactant which have the purpose of increasing the density and decreasing the surface tension of the WO₃ colloidal suspension.

The thick films obtained with this preparation have optimum characteristics for use with:

a) Electrochromic devices

b) Photoelectrocatalitic devices for the oxidation of organic substances and the production of hydrogen.

c) Tandem cells for the oxidation of organic substances and the production of hydrogen from aqueous solutions.

The preparing method described in the present invention is finally cost-effective and can be extended to industrial outputs.

1. A method for preparing a substrate coated with at least one thick layer of tungsten oxide, comprising at least one step of coating said substrate with a tungsten oxide colloidal solution obtained with the sol-gel method, said colloidal solution being additioned with a thickener and a surfactant.

2. The method according to claim 1, wherein said thickener is based on polyethylene glycol.

3. The method according to claim 2, wherein said thickener is polyethylene glycol reacted with bisphenol A diglycidyl ether (Carbowax 20000).

4. The method according to claim 1, wherein said thickener is selected from Mannitol, Glycerol, EthylenGlycol and 200 to about 1000 (average) MW poly PEG.

5. The method according to claim 1, wherein said surfactant is a non-ionic surfactant.

6. The method according to claim 5, wherein said surfactant is a polyethylene glycol-based surfactant.

7. The method according to claim 6, wherein said polyethylene glycol-based surfactant is selected from a polyethylene glycol or a polyethylene glycol-ether or a polyethylene glycol-hexadecyl-ether, or a polyethylene glycol-octadecyl-ether or a polyethylene glycol-dodecyl-ether or a polyoxyethylene-stearyl-ether.

8. The method according to claim 5, wherein said non-ionic surfactant is selected from: Triton X-45, Triton X-100, Triton X-114 Triton X-165, Triton X-305, Triton X-405, Triton X 705-70 Triton CF10, Brij 30, Brij 35 P, Brij 52, Brij 56, Brij 58 P, Brij 72, Brij 76, Brij 78 P, Brij 92V, Brij 96 V.

9. The method according to claim 1, wherein said thickener is added in amount ranging between 15% and 25% w/w.

10. The method according to claim 9, wherein said thickener is added in amount ranging between 18% and 23% w/w.

11. The method according to claim 1, wherein said surfactant is added in an amount ranging between 0.5% and 4%, preferably between 1% and 3% by weight of colloidal paste.

12. The method according to claim 1, wherein the preparation of said colloidal solution of tungsten oxide comprises a step of treating a tungstate salt, preferably a tungstate of an alkali metal such as sodium tungstate (Na₂WO₃), in acidic medium and protic solvent, preferably water, to give a WO₃ gel.

13. The method according to claim 12, wherein said acidic medium is obtained by means of treatment with a strong mineral acid, such as hydrochloric acid.

14. The method according to claim 12, wherein the preparation of said colloidal solution of tungsten oxide comprises a subsequent step of treating said WO₃ gel with an acidic solution at a temperature ranging between 50° C. and 100° C., preferably between 65° C. and 75° C.

15. The method according to claim 1, wherein said at least one step of coating said substrate is carried out with the “doctor blading” method.

16. The method according to claim 1, wherein each of said at least one coating step is followed by a sintering step at a temperature ranging between 500° and 600°.

17. The method according to claim 1, wherein said thick layer of tungsten oxide is 2-3 micron thick.

18. A tungsten oxide colloidal solution, characterized in that it comprises a thickener and a surfactant in such amounts that it allows coating a substrate with a thick layer WO₃ by means of “doctor blading”.

19. The tungsten oxide colloidal solution according to claim 18, which can be obtained by means of a method comprising at least one step of coating said substrate with a tungsten oxide colloidal solution obtained with the sol-gel method, said colloidal solution being additioned with a thickener and a surfactant.

20. Electrochromic devices, particularly glasses, characterized by comprising a tungsten oxide coating obtained by means of a method comprising at least one step of coating said substrate with a tungsten oxide colloidal solution obtained with the sol-gel method, said colloidal solution being additioned with a thickener and a surfactant.

21. Photoelectrocatalytic devices, characterized by comprising a tungsten oxide coating obtained by means of a method comprising at least one step of coating said substrate with a tungsten oxide colloidal solution obtained with the sol-gel method, said colloidal solution being additioned with a thickener and a surfactant.

22. Tandem cells for the oxidation of organic substances and production of hydrogen from aqueous solutions, characterized in that they have a photoanode coated with tungsten oxide obtained with a method comprising at least one step of coating said substrate with a tungsten oxide colloidal solution obtained with the sol-gel method, said colloidal solution being additioned with a thickener and a surfactant.
